(19) United States
(12) Patent Application Publication
(10) Pub. No.: US 2004/0160169 A1
(43) Pub. Date: Aug. 19, 2004

(54) Substrate for an electroluminescent display device and method of manufacturing said substrate

(76) Inventor: Henricus Franciscus Johannus Jacobus Van Tongeren, Eindhoven (NL)

Correspondence Address: U S Philips Corporation, Intellectual Property Department, PO Box 3001, Briarcliff Manor, NY, 10510, US

(21) Appl. No.: 10/480,417

(22) PCT Filed: Jun. 20, 2002
(86) PCT No.: PCT/IB02/02370

(30) Foreign Application Priority Data
Jun. 25, 2001 (EP) 01202431.1

(51) Int. Cl. H05B 33/00

(52) U.S. Cl. 313/504

(57) ABSTRACT

The invention relates to a substrate for an electroluminescent (EL) display device comprising a front surface and a rear surface (7) onto which EL elements are to be arranged. The substrate comprises a plurality of reflectors (5) diverging towards the front surface. Furthermore, the relatively narrow ends (6) of the reflectors (5) are at least substantially coplanar and form part of said rear surface (7). The substrate according to the invention can be used in conventional processes of manufacturing EL devices.

The invention relates to a substrate for an electroluminescent (EL) display device comprising a front surface and a rear surface onto which EL elements are to be arranged. The invention further relates to a display device and a method of manufacturing said substrate.

Due to internal reflections at the substrate-air interface of the front surface of a substrate, which is part of an electroluminescent display device, only about half of the amount of light produced by the EL elements arranged on the rear surface will actually be emitted towards an observer. One way of reducing internal reflections is to provide the front surface with an optical pattern, e.g. comprising prisms or lenses. However, especially when substrates having a considerable thickness are employed, optical crosstalk may spoil the visibility of the displayed image. Furthermore, the front surface will not be flat and, consequently, it will be difficult to apply protective or filtering layers without destroying the performance of the pattern.

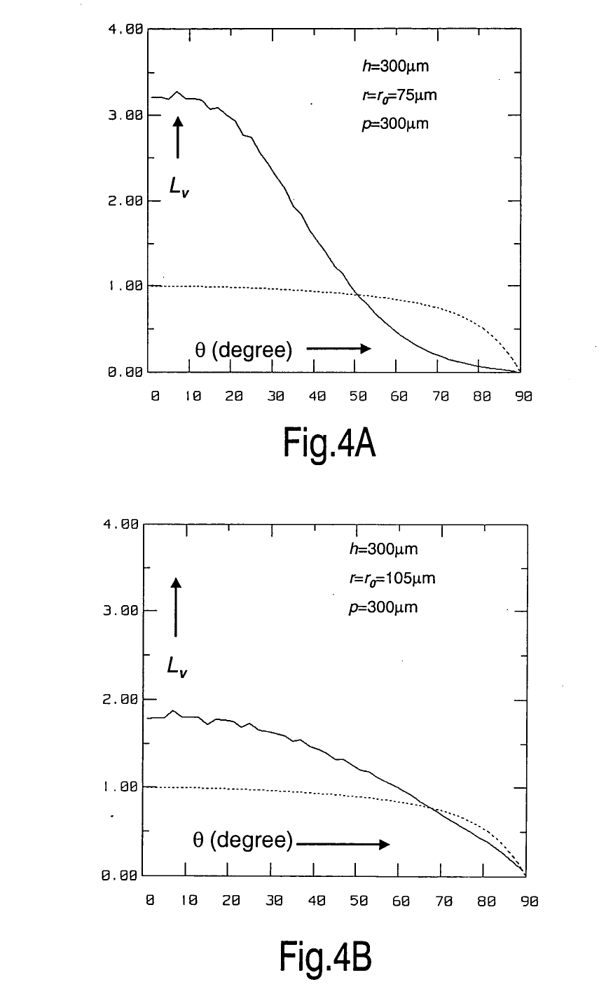

Another way of reducing internal reflections is to provide reflectors with which light that would otherwise be trapped in the substrate is redirected towards the observer. An example of such a structure is known from U.S. Pat. No. 6,091,195, which describes an electronic display for use in devices such as television sets, computer terminals, telecommunication equipment, etc. A specific method of making multicolor LEDs on a common substrate is illustrated in FIGS. 4A to 4D and involves, inter alia, the following steps: depositing a transparent 5 to 10 μm dielectric layer (numeral 19 in said Figures) onto a substrate (37); depositing a green phosphor layer (22), an etch-stop layer (23) and a red phosphor layer (21); several photolithographic patterning steps to create two-dimensional mesa-structures (FIG. 4B) and remove said red and green phosphors from specific mesa-structures; depositing and patterning an ITO and a metal layer to obtain contacts (35); depositing an insulation layer (25) and etching windows in the same; depositing a blue OLED layer (20) on the entire structure; and depositing and patterning a metal layer to form row metal stripe contacts and metal reflectors (47) on the sides of the mesas (FIG. 4D).

The electronic display according to U.S. Pat. No. 6,091,195 cannot be manufactured by using an existing and relatively straightforward process involving e.g. inkjet printing of the red, green, and blue emissive layers. Instead, virtually every step of the process is at least to some extent influenced by the fact that mesas and reflectors are included.

It is an object of the present invention to provide a substrate, which allows the manufacture of an EL display device comprising reflectors, without having to redesign the entire process of manufacturing the display device.

To this end, the substrate mentioned in the opening paragraph is characterized in that it comprises a plurality of reflectors diverging towards the front surface, and in that the relatively narrow ends of the reflectors are coplanar and form part of said rear surface. Thus, the EL elements can be arranged on the rear surface of the substrate by means of a process, which is substantially identical to a process for arranging EL elements onto a conventional (glass) flat substrate or requires only few alterations.

It is preferred that the space between the reflectors is filled up with a medium, the outer surface of which is coplanar with the relatively narrow ends of the reflectors. The rear surface of the substrate can thus be made at least substantially flat and can be used in a conventional process for the manufacture of EL display devices with only minor adjustments, such as employing smaller EL elements (as will be explained below in more detail).

The method according to the present invention is characterized by the steps of providing a sheet of a transparent material, forming a plurality of divergent bodies, such as cones or pyramids, of a transparent material in or on a sheet, with the relatively wide ends of said bodies facing the sheet.

It is preferred that space between the reflectors is subsequently filled up with a medium having a lower reflective index than that of the divergent bodies. It is further preferred that part of the relatively narrow ends of the divergent bodies and, if present, said medium are planarized.

The method according to the present invention allows relatively simple manufacture of a substrate which can be used in a conventional process for manufacturing EL display devices.

The invention will now be explained in more detail with reference to the drawings, in which an embodiment of the present invention is shown schematically.

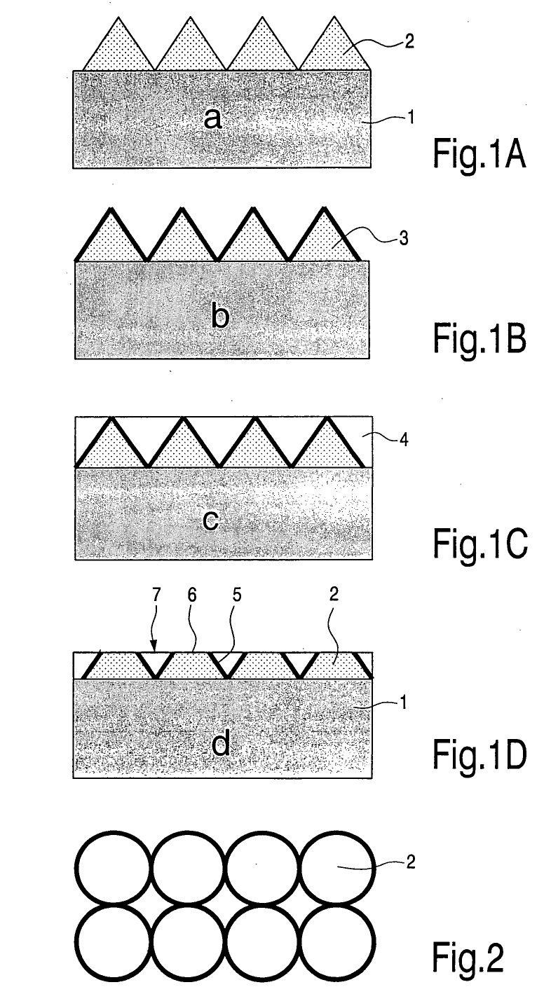

FIGS. 1A to 1D show four steps of a method of manufacturing a display device according to the present invention.

FIG. 2 is a plan view of the intermediate product in accordance with FIG. 1A.

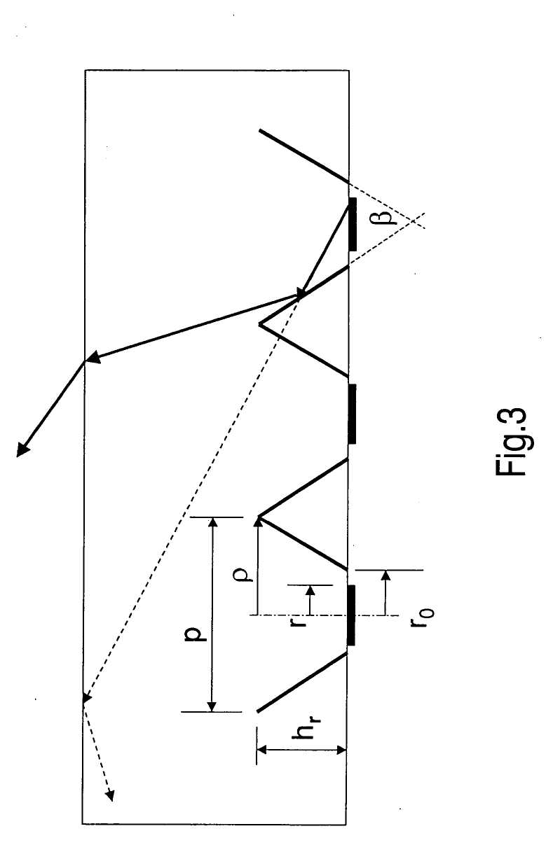

FIG. 3 is a schematic cross-section through a substrate according to the present invention.

FIGS. 4A and 4B show the effects of varying the imaginary apex angle of reflectors comprised in the substrate shown in FIG. 3.

FIGS. 1A to 1D and 2 schematically show a method of manufacturing a substrate according to the present invention, wherein a conventional glass sheet 1 is provided with N rows and M columns of polymer cones 2 (FIGS. 1A and 2), preferably by means of a substantially flat metal die (not shown). Such a die may comprise (a pattern of) recesses which correspond to the shape of the divergent bodies 2, e.g. truncated cones, or recesses which result in precursors of such bodies 2, e.g. complete cones of which the top portion should still be removed. The mentioned polymer is transparent in at least the visible part (from about 400 to about 700 nm) of the spectrum and has a refractive index which is at least substantially equal to that of the glass sheet 1. The refractive index of the divergent bodies should preferably differ no more than 5% from that of the sheet 1. In this particular embodiment, the sheet is made of glass having a refractive index of 1.52. Examples of suitable polymers are UV-curable polymers, such as acrylate laquer #132200040029 (Oss Coatings, Oss, The Netherlands), which has a refractive index of 1.50.

Subsequently, a reflecting layer 3 of e.g. aluminum or silver is arranged on the cones 2 (FIG. 1B) by means of, for instance, vacuum deposition, wet silvering or spincoating. The space between the cones 2 is filled up with an interstitial polymer 4 (FIG. 1C), such as Teflon AF1600 or Teflon AF2400 (both ex Dupont) having a refractive index of 1.3, by means of spincoating. If the interstitial polymer 4 is itself reflecting or has a refractive index which is sufficiently lower than that of the cones 2, a metal reflecting layer will not be required because the interface between the cones 2 and the further polymer will be sufficiently reflective.

By removing the top layer of the structure (FIG. 1D), e.g. by means of polishing, reflectors 5 are obtained, the narrow ends 6 of which are coplanar with respect to each other and form a flat rear surface 7 together with the interstitial polymer 4.

EL elements can be arranged on the narrow ends 6 using methods which are well known to the skilled person. Such methods may involve the deposition of transparent first electrodes (anodes), one or more EL layers, and second electrodes (cathodes), which defined EL elements at the intersection with the first electrodes. In the case of a color display, wherein the EL elements are divided into two or more sub-elements of different color, it is preferred that these sub-elements are configured concentrically, e.g. by printing concentric rings of substantially the same surface area.

It is noted that due to the improvement of the emission efficiency, the reflectors allow the use of EL elements having a reduced area. Smaller EL elements in turn yield a decrease of capacitive, driver, and resistive losses.

Especially when the substrate comprises a metal reflecting layer 3, an insulation layer is preferably deposited on the rear surface 7 of the substrate so as to insulate the EL elements, in particular the electrode(s) nearest the substrate, from this metal reflecting layer 3. The rear surface 7 can also be provided with a planarising layer to further improve its flatness.

The divergent bodies 2 and hence the reflectors 5 may have various shapes, such as a cone, pyramid or dome. Depending on the pitch and dimensions of the EL elements as well as on the requirements of a specific application, the shape of the reflectors can be varied to obtain certain optical characteristics.

As an example, optical modelling by ray tracing was conducted on a truncated cone as shown in FIG. 3. Such a cone is defined by the radii of the narrow and wide ends of the reflectors, denoted by “r₀” and “ρ”, respectively, and by the height “hᵣ” of the truncated cone. FIGS. 4A and 4B show the angular luminance “Lᵥ” as a function of the viewing angle “θ” of a substrate without reflectors (dotted line) and of reflectors having a relatively small (FIG. 4A) and a relatively large (FIG. 4B) imaginary apex angle “β”, respectively; “r” denotes the radius of the emissive elements that are arranged on the reflectors. FIGS. 4A and 4B clearly show that, in both cases, the luminance has a direction normal to the front surface if the substrate is increased considerably and that the angular distribution is modified.

The invention is not limited to the above-described embodiments which can be varied in a number of ways within the scope of the claims.

Within the context of this application, an electroluminescent display device is a device, which, while making use of the phenomenon of electroluminescence, emits light when the device is suitably connected to a power supply. The term electroluminescence includes several phenomena which have the common feature that light is emitted by electrical excitation of gases (for example: plasma display panels), liquids or solid materials (for example: organic LED display panels).

In summary, the invention relates to a substrate for an electroluminescent (EL) display device comprising a front surface and a rear surface onto which EL elements are to be arranged. The substrate comprises a plurality of reflectors diverging towards the front surface. Furthermore, the relatively narrow ends of the reflectors are at least substantially coplanar and form part of said rear surface. The substrate according to the invention can be used in conventional processes of manufacturing EL devices.

1. A substrate for an electroluminescent (EL) display device comprising a front surface and a rear surface (7) onto which EL elements are to be arranged, characterized in that the substrate comprises a plurality of reflectors (5) diverging towards the front surface and in that the relatively narrow ends (6) of the reflectors (5) are at least substantially coplanar and form part of said rear surface (7).

2. A substrate as claimed in claim 1, wherein the space between the reflectors (5) is filled up with a medium (4), the outer surface of which is coplanar with the relatively narrow ends (6) of the reflectors (5).

3. A substrate as claimed in claim 1 or 2, wherein the reflectors (5) comprise a divergent body (2), such as a truncated cone or pyramid, of a transparent material and wherein the divergent surface of this body (2) is provided with a reflecting layer (3).

4. A substrate as claimed in any one of the preceding claims, wherein the reflectors (5) are arranged in rows and columns.

5. A display device comprising a substrate as claimed in any one of the preceding claims, wherein emissive elements are arranged on at least some of the narrows ends (6) of the reflector (5).

6. A method of manufacturing a substrate for an EL device, the method comprising the steps of providing a sheet (1) of a transparent material, forming a plurality of divergent bodies (2), such as cones or pyramids, of a transparent material in or on a sheet (1), with the relatively wide ends of said bodies (2) facing the sheet (1).

7. A method as claimed in claim 6, wherein the divergent bodies (2) are deposited on the sheet (1), preferably by means of a die.

8. A method as claimed in claim 7, wherein the divergent bodies (2) have a refractive index which is at least substantially equal to that of the sheet (1).

9. A method as claimed in any one of claims 6 to 8, wherein a reflecting layer (3) is deposited on the divergent bodies (2).

10. A method as claimed in any one of claims 6 to 9, wherein the space between the divergent bodies (3) is filled up with a medium (4) having a lower refractive index than that of the divergent bodies.

11. A method as claimed in any one of claims 6 to 10, wherein the relatively narrow ends (6) of the divergent bodies (2) and, if present, the medium (4) are planarized.
